(19) United States
(12) Patent Application Publication
(10) Pub. No.: US 2009/0086458 A1
(43) Pub. Date: Apr. 2, 2009

(54) PLASMA DISPLAY APPARATUS

(75) Inventors: Masashi Terauchi, Gunma (JP); Yoshiaki Kurosu, Gunma (JP); Masakazu Ueno, Gunma (JP); Norio Okazaki, Tochigi (JP); Kazumasa Arai, Gunma (JP)

Correspondence Address: FISH & RICHARDSON P.C., P.O. BOX 1022, MINNEAPOLIS, MN, 55440-1022, US

(73) Assignees: Sanyo Electric Co., Ltd., Osaka (JP); Sanyo Semiconductor Co., Ltd., Gunma (JP)

(21) Appl. No.: 12/233,722

(22) Filed: Sep. 19, 2008

(30) Foreign Application Priority Data
Sep. 27, 2007 (JP) 2007-250482

(51) Int. Cl. H05K 7/06

(52) U.S. Cl. 361/809

(57) ABSTRACT

In plasma displays in different inch sizes, there is a disadvantage in that because each of the plasma displays in different inch sizes has an output semiconductor device with a different outer shape, a pitch of the external lead and the number of the output semiconductor devices vary, so that printed circuit boards need be designed differently for the different inch sizes. A hybrid integrated circuit includes mounting portions which are composed of a conductive path on an insulated metal substrate, and into which at least an output semiconductor device of a discharge maintaining circuit is incorporated, and includes external terminals arranged at a constant pitch. When the inch size of the plasma display is changed, the mounting portions are designed to have a size enough to accommodate the output semiconductor device for the greatest inch size. Thus, the same hybrid integrated circuit is commonly used.

This application claims priority from Japanese Patent Application Number JP 2007-250482 filed on Sep. 27, 2007, the content of which is incorporated herein by reference in its entirety.

### BACKGROUND OF THE INVENTION

1. Field of the Invention

The present invention relates to a plasma display apparatus using a hybrid integrated circuit that incorporates a discharge maintaining circuit of a plasma display for large-sized flat televisions.

2. Description of the Related Art

The plasma display is used on large-sized flat televisions or the like.

As shown in FIG. 4, an image control circuit 13 of a plasma display sends control signals to an address driver and a scan driver, and maps a luminous unit (cell). Next, the image control circuit sends control signals to discharge maintaining circuits 12A and 12B as shown in FIG. 5A, and makes the cell discharge at intervals of four microseconds. Mapping is performed in every gradation of brightness (subfield=one millisecond), an image of one frame is achieved by discharging, and the mapping and the discharging are repeated at 60 frames per second, thereby achieving moving pictures. This technology is described for instance in Japanese Patent Application Publication No. 2006-171180.

As shown in FIG. 6, in the discharge maintaining circuits 12A and 12B, supply voltages from a power supply circuit 10 are applied to bootstrap capacitors C1, C3, and C4. Furthermore, pulse signals of 250 kHz are applied to a terminal HIN and a terminal LIN of a driver IC 17 from the image control circuit 13, so that pulse signals of 250 kHz are generated from a terminal HO and a terminal LO of the driver IC 17.

The high-level pulse signal generated from the terminal HO of the driver IC 17 is applied to bases of switching transistors Q1 and Q2 in a pre-driver 18 so that the switching transistor Q1 is turned ON and the transistor Q2 is turned OFF. Accordingly, the discharge voltage of the electric charge that is charged in the bootstrap capacitors C1 and C3 while the switching transistor Q1 is OFF, is superimposed on the supply voltage via the switching transistor Q1, and is applied to gates of IGBT1 (insulated gate bipolar transistor 1) and IGBT2 in a driver 19 via the switching transistor Q1 so that the IGBT1 and the IGBT2 that are output semiconductor devices in the driver 19 are turned ON. On the other hand, IGBT3 and IGBT4 that are output semiconductor devices for electric discharge in the driver 19 are turned OFF.

In this manner, the pulse signal of 250 kHz generated from the image control circuit 13 is driven with the cycles of 1 kHz and 60 Hz, and controlling the electric discharge of the plasma display is performed.

In such plasma displays, each cell has an electrode with different size depending on the inch size of the plasma display, and the size of the electric charge for discharge also varies so that output capacities of the IGBT1, the IGBT2, the IGBT3, and the IGBT4 in the driver 19 need to be changed.

FIG. 8 shows a case where the above-described driver 19 is composed of discrete output semiconductor devices. Although one output semiconductor device is present on the circuit diagram, multiple output semiconductor devices are connected in parallel depending on the size of the current flown. In a 37-inch plasma display, about five semiconductor devices each having an outer shape of TO-220 are attached to a radiator to design a printed circuit board. In a 42-inch plasma display, four semiconductor devices each having an outer shape of TO-220 and about one semiconductor device of TO-3P larger in size than the TO-220 are attached to a radiator to design a printed circuit board. In a 50-inch plasma display, five semiconductor devices each having an outer shape of TO-220 and about one semiconductor device of TO-3P larger in size than the TO-220 are attached to a radiator to design a printed circuit board. The standardized external lead pitches are 2.54 mm for TO-220, and 5.45 mm for TO-3P.

However, there is a disadvantage in that because each of the plasma displays in different inch sizes has the output semiconductor device with a different outer shape, a pitch of the external lead is different and the number of the output semiconductor devices is different, so that printed circuit boards designed differently for the respective inch sizes are required.

### SUMMARY OF INVENTION

In view of the above-described disadvantage, according to a first aspect of the present invention, a plasma display apparatus includes a discharge maintaining circuit of each cell connected to a plasma display, and a hybrid integrated circuit into which at least an output semiconductor device of the discharge maintaining circuit is incorporated on a mounting portion formed of a conductive path on an insulated substrate, the hybrid integrated circuit including external terminals arranged at a constant pitch. In the plasma display apparatus, the mounting portion is designed to have a size enough to accommodate the output semiconductor device for the greatest inch size, so that the output semiconductor device according to the inch size is fixed to the mounting portion, and that the external terminals maintain the constant pitch, even when the inch size of the plasma display is changed and thus the size of the output semiconductor device is changed.

Furthermore, according to the first aspect, the hybrid integrated circuit is formed in the same outer shape for the plasma displays in different inch sizes.

Furthermore, according to the first aspect, the hybrid integrated circuit is formed in a SIP structure for the plasma displays in different inch sizes.

### BRIEF DESCRIPTION OF THE DRAWINGS

FIG. 1 is a top view for explaining a hybrid integrated circuit in use in a preferred embodiment of the present invention;

FIG. 2 is another top view for explaining the hybrid integrated circuit in use in the preferred embodiment;

FIG. 3 is still another top view for explaining the hybrid integrated circuit in use in the preferred embodiment;

FIG. 4 is a block diagram of a discharge control circuit of a plasma display incorporated in the hybrid integrated circuit according to the preferred embodiment;

FIGS. 5A and 5B are diagrams showing pulse signal waveforms of FIG. 4, FIG. 5A is a diagram showing a signal waveform in one subfield, and FIG. 5B is a diagram showing a signal waveform in one frame;

FIG. 6 is a discharge maintaining circuit diagram for explaining a pulse drive portion in the hybrid integrated circuit according to the preferred embodiment;

FIG. 7 is a cross-sectional view showing the hybrid integrated circuit in use in the preferred embodiment; and

FIG. 8 is a perspective view showing a printed circuit board on which a conventional discharge control circuit of a plasma display is mounted.

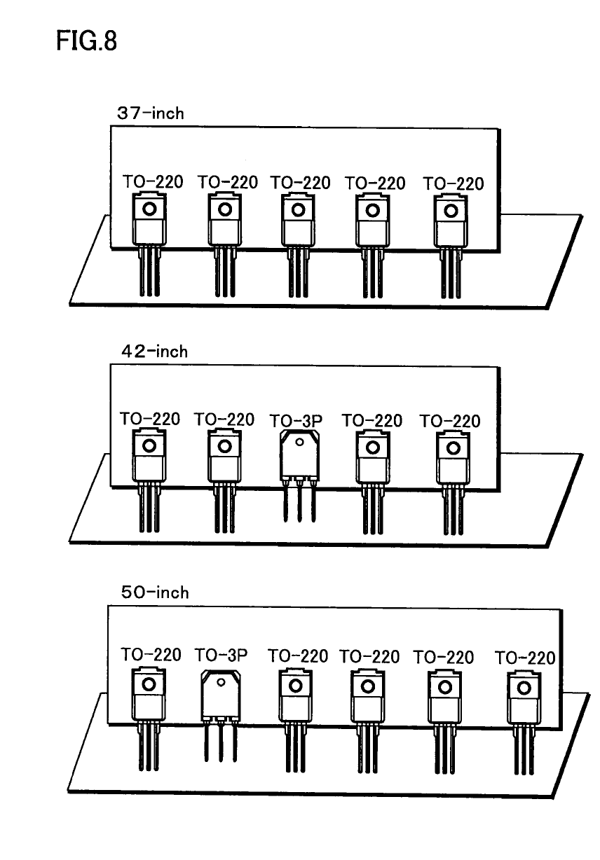

### DESCRIPTION OF THE INVENTION

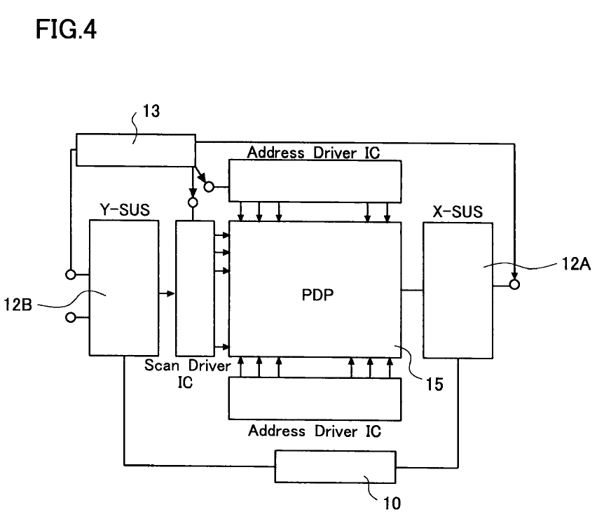

FIG. 4 is a block diagram of an image control circuit of a plasma display of a preferred embodiment of the present invention.

A scan driver of the plasma display includes the power supply circuit 10, the discharge maintaining circuits 12A and 12B, and a plasma display 15.

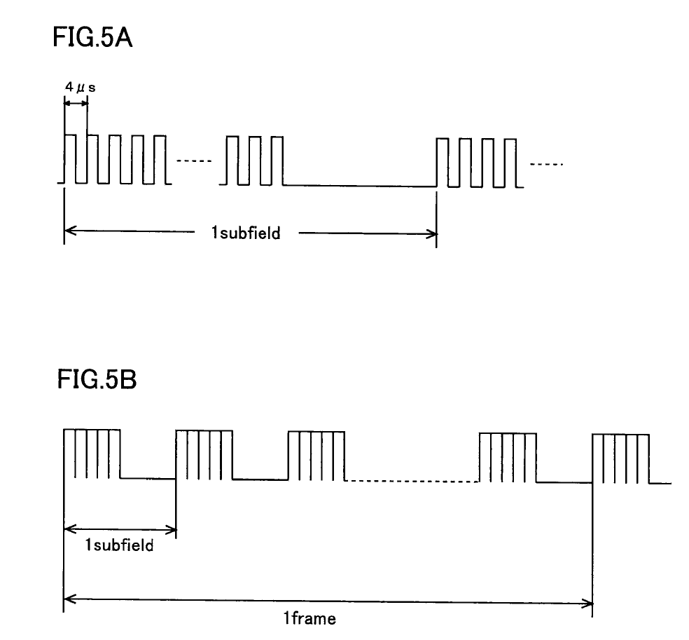

As shown in FIG. 5A, when control voltages are applied to the discharge maintaining circuits 12A and 12B from the image control circuit 13, a pulse signal of 250 kHz is generated during one subfield (one millisecond) from the discharge maintaining circuits 12A and 12B, and address scan mapping is performed.

As shown in FIG. 5B, such operation is repeated so as to display moving pictures with 60 frames per second.

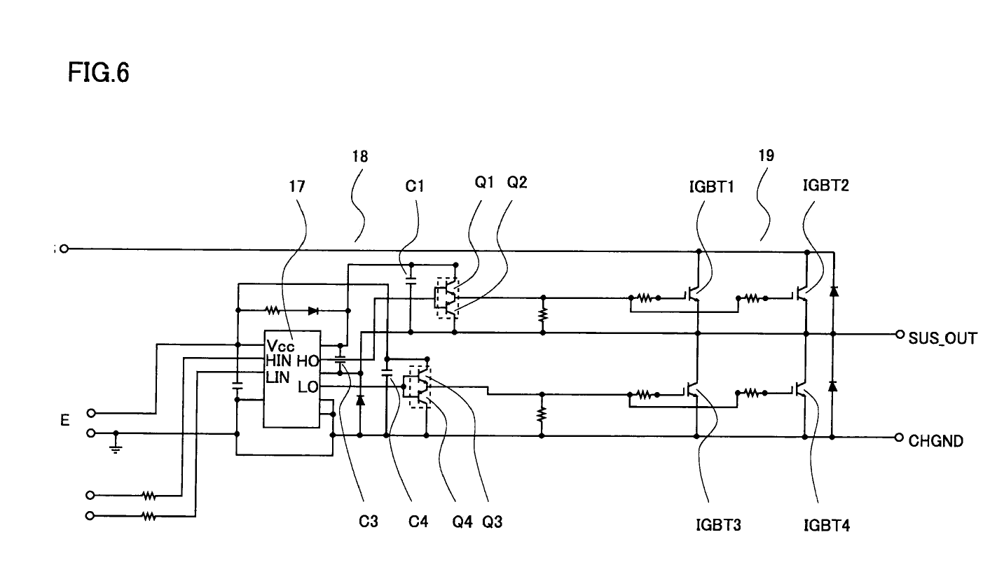

FIG. 6 is a circuit diagram of the discharge maintaining circuits 12A and 12B formed in a hybrid integrated circuit according to the preferred embodiment.

The discharge maintaining circuits 12A and 12B include the driver IC 17, the pre-driver 18 composed of the switching transistors Q1, Q2, Q3, and Q4 and the bootstrap capacitors C1, C3, and C4, and the driver 19 composed of the IGBT1, the IGBT2, the IGBT3, and the IGBT4. The bootstrap capacitors C1, C3, and C4 are ceramic capacitors.

Next, the operation by the discharge maintaining circuits 12A and 12B will be described. Supply voltages from the power supply circuit 10 are applied to the bootstrap capacitors C1, C3, and C4. Furthermore, a pulse signal of 250 kHz is applied to the terminal HIN and the terminal LIN of the driver IC 17 from the image control circuit 13, so that the voltage-changed pulse signals of 250 kHz are generated from the terminal HO and the terminal LO of the driver IC 17.

The high-level pulse signal generated from the terminal HO of the driver IC 17 is applied to bases of the switching transistors Q1 and Q2 in the pre-driver 18, so that the switching transistor Q1 is turned ON and the transistor Q2 is turned OFF. Accordingly, the discharge voltage of the electric charge that is charged in the bootstrap capacitor C1 while the switching transistor Q1 is OFF, is superimposed on the supply voltage via the switching transistor Q1, and is applied to gates of the IGBT1 and the IGBT2 in the driver 19 via the switching transistor Q1, so that the IGBT1 and the IGBT2 in the driver 19 are turned ON.

As described above, although the pulse signal applied to the bases of the pre-driver 18 from the driver IC 17 was 5 V, the driving voltages of the IGBT1 and the IGBT2 in the driver 19 are boosted in the range of 15 V to 18 V in the pre-driver 18. The driving voltages are boosted in the range of 15 V to 18 V, so that the loss of the IGBT1 and the IGBT2 decreases.

When the IGBT1 and the IGBT2 turn ON, the supply voltage from a terminal VS is outputted to a terminal SUS_OUT via the IGBT1 and the IGBT2.

In this manner, the pulse signal of 250 kHz generated from the image control circuit 13 and 1 kHz and 60 Hz pulse signals are applied to the terminal SUS_OUT of the plasma display 15, thereby achieving a moving picture of one field with 60 frames per second and electric discharging for one subfield.

Similarly, the low-level pulse signal generated from the terminal LO of the driver IC 17 is applied to bases of the switching transistors Q3 and Q4 in the pre-driver 18, so that the switching transistor Q4 is turned ON and the transistor Q3 is turned OFF. Accordingly, the discharge voltage of the electric charge that is charged in the bootstrap capacitors C3 and C4 while the switching transistor Q4 is OFF, is superimposed via the switching transistor Q4, and is applied to gates of the IGBT3 and the IGBT4 in the driver 19 via the switching transistor Q4, so that the IGBT3 and the IGBT4 in the driver 19 are turned ON.

Because the IGBT3 and the IGBT4 are caused to turn ON when the IGBT1 and the IGBT2 is OFF, the electric charge that is accumulated while the IGBT1 and the IGBT2 are ON is caused to flow to a CHGND terminal via the IGBT3 and the IGBT4, thereby falling down to a GND level.

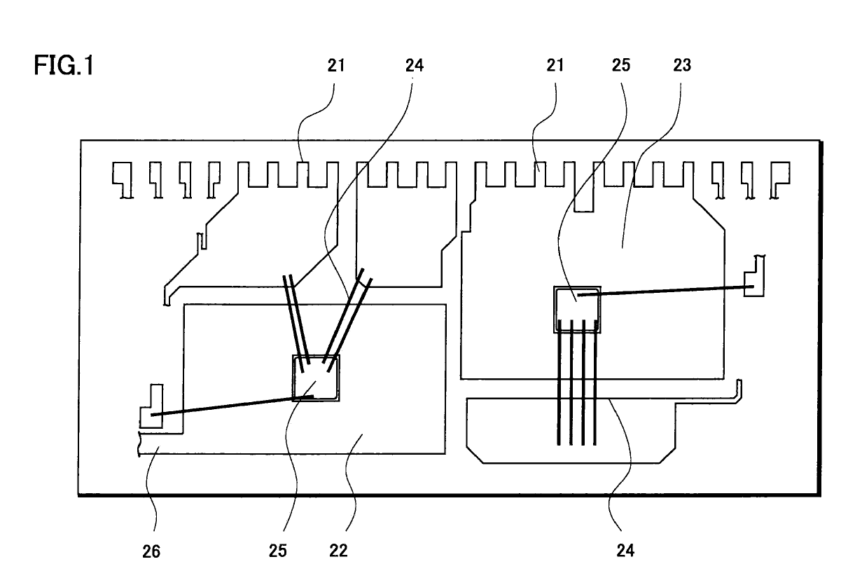

FIG. 1 to FIG. 3 are top views each showing a hybrid integrated circuit according to the preferred embodiment, and a discharge maintaining circuit of a plasma display is incorporated into the hybrid integrated circuit.

FIG. 1 is a top view of a hybrid integrated circuit into which a discharge maintaining circuit of a 37-inch plasma display is incorporated. External terminal pads 21 to which external terminals are connected by soldering are arranged at a constant pitch at the upper end of the hybrid integrated circuit. Mounting portions 22 and 23 are provided on the center portion thereof. The above-described IGBT1 and the IGBT2 are mounted on the mounting portion 22, and the above-described IGBT3 and the IGBT4 are mounted on the mounting portion 23. The mounting portions 22 and 23 are designed in advance to have enough size to incorporate the IGBT1 and the IGBT2, and the IGBT3 and the IGBT4 in the discharge maintaining circuit of the plasma display having any size of 37 to 50 inches. In the hybrid integrated circuit of a 37-inch plasma display, one IGBT bear chip 25 is fixed to each of the mounting portions 22 and 23, and is connected to the corresponding electrodes with metal thin wires 24.

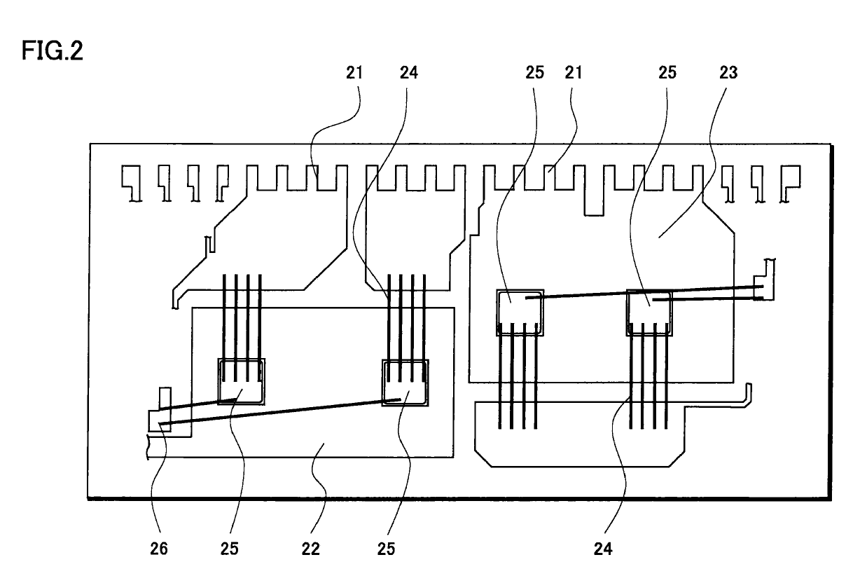

FIG. 2 is a top view of a hybrid integrated circuit into which a discharge maintaining circuit of a 42-inch plasma display is incorporated. Two IGBT bear chips 25 are fixed to each of the mounting portions 22 and 23, and are connected to the corresponding electrodes via the metal thin wires 24.

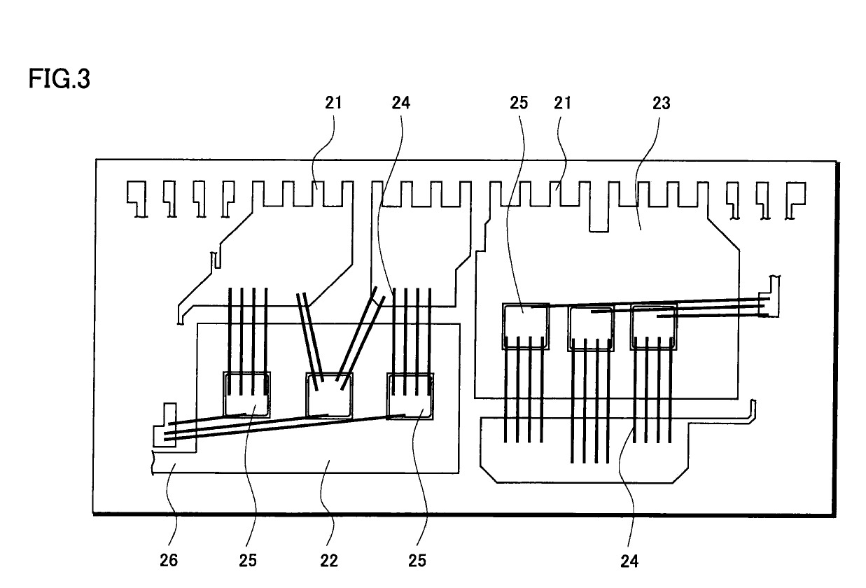

FIG. 3 is a top view of a hybrid integrated circuit into which a discharge maintaining circuit of a 50-inch plasma display is incorporated. Three IGBT bear chips 25 are fixed to each of the mounting portions 22 and 23, and are connected to the corresponding electrodes via the metal thin wires 24.

Although the IGBT bear chips each having the same size are used in the examples described above, the IGBT chip size may be changed. The mounting portions 22 and 23 are designed to have a size enough to incorporate the output semiconductor device in the discharge maintaining circuit of a plasma display having the greatest inch size.

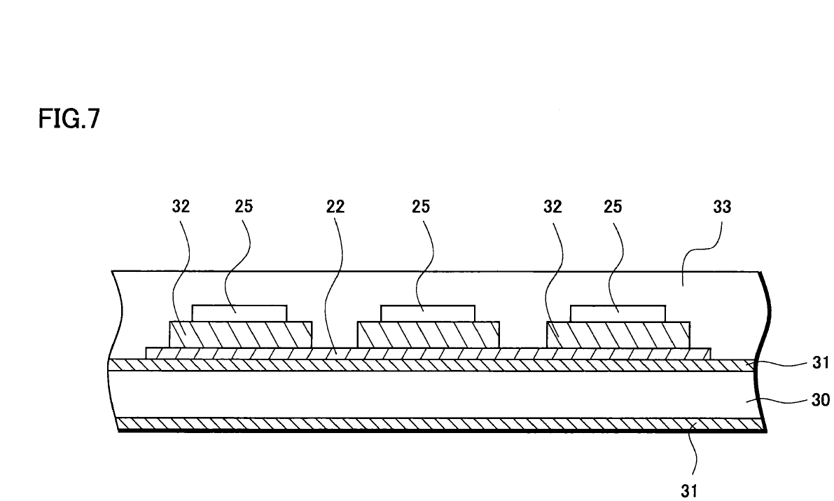

Nest, referring to FIG. 7, the structure of the hybrid integrated circuit will be described. In the hybrid integrated circuit, a surface of a metal substrate 30 made of aluminum is insulated and is covered with an aluminum oxide layer 31, and copper foil is fixed thereon followed by etching. In this way, the external terminal pads 21, a conductive path 26, and the mounting portions 22 and 23 are formed. The mounting portion is designed to have such a size that three or more IGBT bear chips are fixed. The IGBT bear chips 25 in the number that is enough to secure required current capacity, are fixed thereon by soldering via a heat sink 32. An emitter electrode and a gate electrode of IGBT are connected to the conductive path 26 with the metal thin wires 24 by bonding. Because fixing of IGBT and bonding of the metal thin wires 24 are performed by using pattern recognition, flexibility thereof is very high. Accordingly, IGBT can be fixed to the mounting portions 22 and 23 with flexibility, and is connected to the conductive path 26 with the metal thin wires 24. Thus, even if any number of IGBTs are fixed to the mounting portions 22 and 23, IGBTs can be connected to the conductive path 26.

In addition, because the insulated metal substrate is employed, a heat dissipation characteristic is good. There is no problem with regard to the heat dissipation characteristic for discharge maintaining circuits of plasma displays of 37 to 50 inches. Thus, each of the hybrid integrated circuits may have the same outer shape. Even if each of the hybrid integrated circuits employs a single inline package (SIP) structure in which the external terminals direct to one direction, the pitches of the external terminals are made uniform. Accordingly, the same printed circuit board on which the hybrid integrated circuit is to be mounted can be used for the plasma displays, because the outer shape of the hybrid integrated circuit is same and the pitch between the external terminals of each printed circuit board is not changed. Furthermore, in the hybrid integrated circuit, the whole insulated metal substrate are sealed with a mold resin 33 such as a epoxy resin by transfer molding, while the rear surface of the insulated metal substrate 30 is exposed.

According to the preferred embodiment, at least an output semiconductor device of the discharge maintaining circuit of each cell to be connected to a plasma display is incorporated into a hybrid integrated circuit having a mounting portion composed of a conductive path on an insulated metal substrate. When the mounting portion is designed to have such a size that bear chips of an output semiconductor device of a plasma display having the greatest inch size, the discharge maintaining circuit of the plasma display having the inch size other than the greatest inch size can be incorporated into a common hybrid integrated circuit. Because the hybrid integrated circuit has external terminals arranged at a constant pitch, the same printed circuit board on which the hybrid integrated circuit is to be mounted can be advantageously used for the plasma displays in different inch sizes.

Furthermore, because using the insulated metal substrate, the hybrid integrated circuit has an excellent heat dissipation characteristic. Thus, discharge maintaining circuits for plasma displays of various inch sizes can be obtained by commonly using a hybrid integrated circuit of a single type.

What is claimed is:

1. A plasma display apparatus comprising:
a discharge maintaining circuit of each cell connected to a plasma display, and
a hybrid integrated circuit into which at least an output semiconductor device of the discharge maintaining circuit is incorporated on a mounting portion formed of a conductive path on an insulated metal substrate, the hybrid integrated circuit including external terminals arranged at a constant pitch, wherein
the mounting portion is designed to have a size enough to accommodate the output semiconductor device for the greatest inch size, so that the output semiconductor device according to the inch size is fixed to the mounting portion, and that the external terminals maintain the constant pitch, even when the inch size of the plasma display is changed and thus the size of the output semiconductor device is changed.

2. The plasma display apparatus according to claim 1, wherein the hybrid integrated circuit is formed in the same outer shape for the plasma displays in different inch sizes.

3. The plasma display apparatus according to claim 1, wherein the hybrid integrated circuit is formed in a SIP structure for the plasma displays in different inch sizes.
